(19) United States
(12) Patent Application Publication
(10) Pub. No.: US 2014/0159236 A1
(43) Pub. Date: Jun. 12, 2014

(54) Semiconductor Device Having High-Density Interconnect Array with Core Pillars Formed With OSP Coating

(71) Applicant: STATS ChipPAC, Ltd., Singapore (SG)

(72) Inventors: BaeYong Kim, Seoul (KR); KiYoun Jang, Kyoungki-do (KR); JoonDong Kim, Kyoungbuk (KR)

(73) Assignee: STATS ChipPAC, Ltd., Singapore (SG)

(21) Appl. No.: 14/181,429

(22) Filed: Feb. 14, 2014

Related U.S. Application Data
(63) Continuation of application No. 12/046,761, filed on Mar. 12, 2008, now abandoned.

(51) Int. Cl. H01L 23/00

(52) U.S. Cl. CPC H01L 24/11; H01L 24/81; H01L 24/13
USPC 257/737; 438/614; 438/107

(57) ABSTRACT

An interconnect structure for a semiconductor device is made by forming a contact pad on a substrate, forming an under bump metallization layer over the contact pad, forming a photoresist layer over the substrate, removing a portion of the photoresist layer to form an opening which exposes the UBM, depositing a first conductive material into the opening of the photoresist, removing the photoresist layer, depositing a second conductive material over the first conductive material, and coating the second conductive material with an organic solderability preservative. The interconnect structure is formed without solder reflow. The first conductive layer is nickel and the second conductive layer is copper. The organic solderability preservative is made with benzotriazole, rosin, rosin esters, benzimidazole compounds, or imidazole compounds. The interconnect structure decreases the pitch between the core pillars in the interconnect array and increases the density of I/O contacts on the semiconductor device.

### CLAIM TO DOMESTIC PRIORITY

The present application is a continuation of U.S. application Ser. No. 12/046,761, filed Mar. 12, 2008, which application is incorporated herein by reference.

### FIELD OF THE INVENTION

The present invention relates in general to semiconductor devices and, more particularly, to a semiconductor device having a high-density interconnect array formed with core pillars having coating of organic solderability preservative to produce a finer pitch and high-density I/O by avoiding solder reflow.

### BACKGROUND OF THE INVENTION

Semiconductor devices are found in many products in the fields of entertainment, communications, networks, computers, and household markets. Semiconductor devices are also found in military, aviation, automotive, industrial controllers, and office equipment. The semiconductor devices perform a variety of electrical functions necessary for each of these applications.

The manufacture of semiconductor devices involves formation of a wafer having a plurality of die. Each semiconductor die contains hundreds or thousands of transistors and other active and passive devices performing a variety of electrical functions. For a given wafer, each die from the wafer typically performs the same electrical function. Front-end manufacturing generally refers to formation of the semiconductor devices on the wafer. The finished wafer has an active side containing the transistors and other active and passive components. Back-end manufacturing refers to cutting or singulating the finished wafer into the individual die and then packaging the die for structural support and environmental isolation.

One goal of semiconductor manufacturing is to produce a package suitable for faster, reliable, smaller, and higher-density integrated circuits (IC) at lower cost. Flip chip packages or wafer level packages (WLP) are ideally suited for ICs demanding high speed, high density, and greater pin count. Flip chip style packaging involves mounting the active side of the die facedown toward a chip carrier substrate or printed circuit board (PCB). The electrical and mechanical interconnect between the active devices on the die and conduction tracks on the carrier substrate is achieved through a solder bump structure comprising a large number of conductive solder bumps or balls. The solder bumps are formed by a reflow process applied to solder material deposited on metal contact pads which are disposed on the semiconductor substrate. The solder bumps are then soldered to the carrier substrate. The flip chip semiconductor package provides a short electrical conduction path from the active devices on the die to the carrier substrate in order to reduce signal propagation, lower capacitance, and achieve overall better circuit performance.

FIG. 1 illustrates a portion of a conventional flip chip 10 with a core pillar and solder bump 11 formed on silicon substrate 12. FIG. 2 describes the process of forming the core pillar and solder bump 11. In step 30, the incoming wafer undergoes cleaning. In step 32, metal contact pad 14 is formed on substrate 12 by sputtering. Contact pad 14 is made of aluminum, copper, or aluminum/copper alloys. Contact pad 14 is electrically connected to active and passive devices through conduction tracks or layers formed on substrate 12. An insulating layer 16 is formed over substrate 12 and contact pad 14. The insulating layer 16 can be made with silicon nitride (SiN), silicon dioxide (SiO2), silicon oxynitride (SiON), polyimide, benzocyclobutene (BCB), polybenzoxazole (PBO), or other insulating material. A portion of insulating layer 16 is removed by an etching process to expose metal contact pad 14. An under bump metallization (UBM) 18 is deposited and patterned to electrically connect to contact pad 14. In one embodiment, UBMs 18 may include a wetting layer, barrier layer, and adhesive layer.

In steps 34 and 36 of FIG. 2, a photoresist layer 54 is coated, exposed, developed, and etched to form a first opening or column having a width which is less than that of contact pad 14 and UBM 18. The first opening is located central to contact pad 14 and UBM 18, as shown in FIG. 3. In step 38, an inner core pillar 20 is plated into the first opening between photoresist layers 54. Core pillar 20 electrically connects to UBM 18 and contact pad 14. Core pillar 20 is made of Cu. An electrically conductive solder material is deposited over pillar 20 through an evaporation, electrolytic plating, electroless plating, ball drop, or screen printing process. The solder material can be any metal or electrically conductive material, e.g., Sn, Pb, Ni, Au, Ag, Cu, Bi, and alloys thereof. In step 40, photoresist layer 54 is removed. In step 42, the solder material is reflowed by heating the solder material above its melting point to form solder bumps 22 on core pillars 20, as seen in the final structure of FIG. 1.

Many interconnect structures for flip chips use a version of the above-described core pillar and solder bumps in an interconnect array. The core pillar and solder bumps are common in high-density arrays having many input/output (I/O) terminals for routing electrical signals. The core pillar and solder bump structures require solder deposition and solder reflow to preserve the insulating layer. The solder deposition and reflow processes limit the density of the core pillars and solder bumps that can be formed per unit area in the interconnect array.

A need exists for high-density interconnect structures without solder deposition or solder reflow to form the core pillars.

### SUMMARY OF THE INVENTION

In one embodiment, the present invention is a method of making a semiconductor device comprising the steps of providing a first substrate, forming a contact pad over the first substrate, forming an insulating layer over the first substrate and contact pad, forming a UBM layer over the contact pad and insulating layer, forming a plurality of core pillars over the UBM layer by electroless plating or electrolytic plating to reduce pitch and increase density of the core pillars, depositing a copper layer over the core pillars, and coating the copper layer over the core pillars with an OSP by (a) first acidic cleaning of the copper layer, (b) first water rinsing the copper layer after the first acidic cleaning, (c) micro-etching of the copper layer after the first water rinsing, (d) second water rinsing of the copper layer after the micro-etching, (e) second acid cleaning of the copper layer after the second water rinsing, (f) third water rinsing of the copper layer after the second acid cleaning, (g) first applying of air knife to the copper layer after third water rinsing, (h) applying the OSP to the copper layer after the first applying of the air knife by immersion in an aqueous solution including copper ions and a benzimidazole, phenylimidazole or other imidazole compound for less than one minute at a temperature range of 40-45° C. to completely cover and protect the copper layer from oxidation, (i) second applying of air knife to the OSP, (j) fourth water rinsing of the OSP after the second applying of the air knife, and (k) drying the OSP to expel moisture.

In another embodiment, the present invention is a method of making a semiconductor device comprising the steps of providing a first substrate, forming a plurality of core pillars over the first substrate by electroless plating or electrolytic plating, depositing a conductive layer over the core pillars, and forming an OSP over the conductive layer by (a) first acidic cleaning of the conductive layer, (b) first water rinsing the conductive layer, (c) micro-etching of the conductive layer, (d) second water rinsing of the conductive layer, (e) second acid cleaning of the conductive layer, (f) third water rinsing of the conductive layer, (g) applying the OSP to the conductive layer by immersion in an aqueous solution including copper ions, (h) fourth water rinsing of the OSP, and (i) drying the OSP to expel moisture.

In another embodiment, the present invention is a method of making a semiconductor device comprising the steps of providing a first substrate, forming a plurality of core pillars over the first substrate without reflow to reduce pitch and increase density of the core pillars, depositing a conductive layer over the core pillars, and forming an OSP over the conductive layer to completely cover and protect the conductive layer from oxidation.

In another embodiment, the present invention is a semiconductor device comprising a first substrate and plurality of core pillars electroless plated or electrolytic plated over the first substrate. A conductive layer is formed over the core pillars. An OSP completely covers the conductive layer to protect the conductive layer from oxidation.

### BRIEF DESCRIPTION OF THE DRAWINGS

FIG. 1 is a conventional core pillar and solder bump formed on a contact pad of a flip chip;

FIG. 2 is a known process for forming the core pillar and solder bump;

FIG. 3 illustrates conventional deposition of metal and solder material into photoresist opening to form the core pillar and solder bump;

FIG. 4 is a flip chip semiconductor device with solder bumps providing electrical interconnect between an active area of the die and a chip carrier substrate;

FIG. 5 illustrates a core pillar interconnect structure for a high-density interconnect array coated with organic solderability preservative;

FIG. 6 is a process for forming the core pillar in the high-density interconnect array using an OSP coating;

FIG. 7 illustrates deposition of a first metal into photoresist openings to form the core pillar;

FIG. 8 illustrates deposition of a second metal layer and OSP coating over the core pillar;

FIG. 9 shows the core pillars coated with OSP in physical contact with solder bumps on a carrier substrate; and

FIG. 10 illustrates reflow of carrier substrate solder bumps to metallurgically connect to the core pillars.

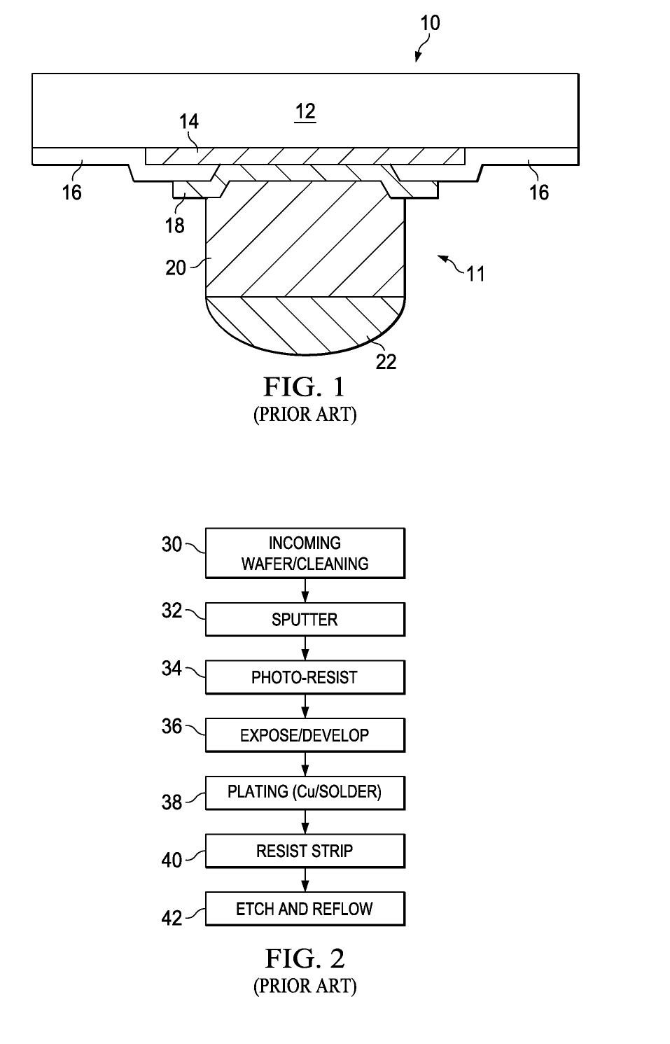

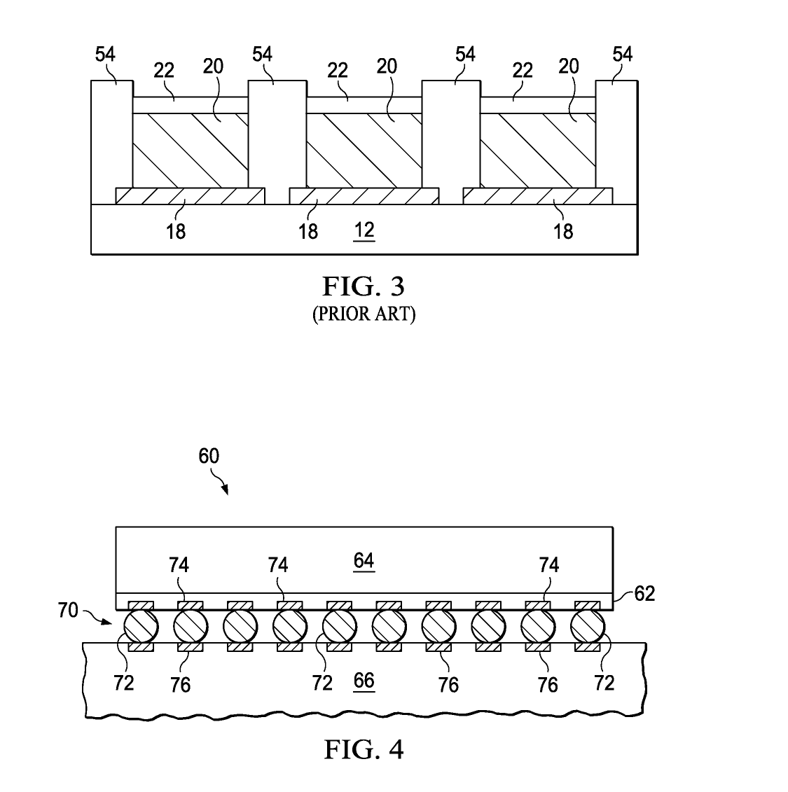

### DETAILED DESCRIPTION OF THE DRAWINGS

The present invention is described in one or more embodiments in the following description with reference to the Figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

The manufacture of semiconductor devices involves formation of a wafer having a plurality of die. Each die contains hundreds or thousands of transistors and other active and passive devices performing one or more electrical functions. For a given wafer, each die from the wafer typically performs the same electrical function. Front-end manufacturing generally refers to formation of the semiconductor devices on the wafer. The finished wafer has an active side containing the transistors and other active and passive components. Back-end manufacturing refers to cutting or singulating the finished wafer into the individual die and then packaging the die for structural support and/or environmental isolation.

A semiconductor wafer generally includes an active surface having semiconductor devices disposed thereon, and a backside surface formed with bulk semiconductor material, e.g., silicon. The active side surface contains a plurality of semiconductor die. The active surface is formed by a variety of semiconductor processes, including layering, patterning, doping, and heat treatment. In the layering process, semiconductor materials are grown or deposited on the substrate by techniques involving thermal oxidation, nitridation, chemical vapor deposition, evaporation, and sputtering. Photolithography involves the masking of areas of the surface and etching away undesired material to form specific structures. The doping process injects concentrations of dopant material by thermal diffusion or ion implantation.

Flip chip semiconductor packages and wafer level packages (WLP) are commonly used with integrated circuits (ICs) demanding high speed, high density, and greater pin count. Flip chip style semiconductor device 60 involves mounting an active area 62 of die 64 facedown toward a chip carrier substrate or printed circuit board (PCB) 66, as shown in FIG. 4. Active area 62 contains active and passive devices, conductive layers, and dielectric layers according to the electrical design of the die. The electrical and mechanical interconnect is achieved through a solder bump structure 70 comprising a large number of individual conductive solder bumps or balls 72. The solder bumps are formed on bump pads or interconnect sites 74, which are disposed on active area 62. The bump pads 74 connect to the active circuits by conduction tracks in active area 62. The solder bumps 72 are electrically and mechanically connected to contact pads or interconnect sites 76 on carrier substrate 66. The flip chip semiconductor device provides a short electrical conduction path from the active devices on die 64 to conduction tracks on carrier substrate 66 in order to reduce signal propagation, lower capacitance, and achieve overall better circuit performance.

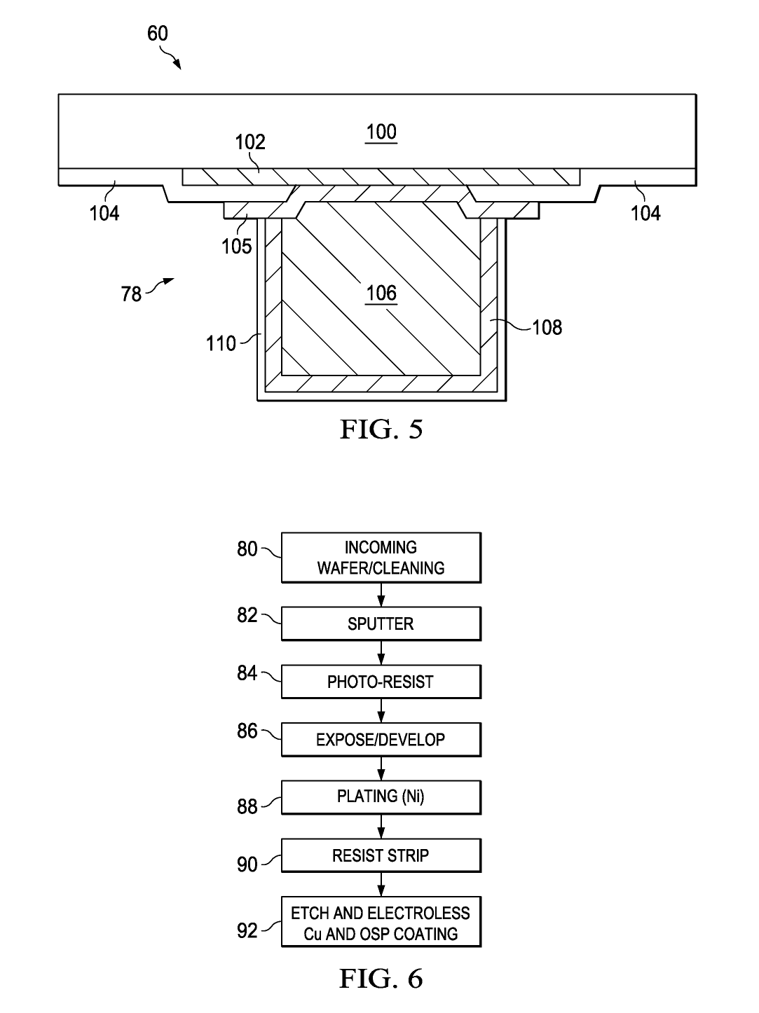

FIG. 5 illustrates a portion of flip chip 60 with a core pillar interconnect structure 78 formed on silicon substrate 100. Flip chip 60 has many input/output (I/O) terminals for routing electrical signals and requires a high-density interconnect array containing a large number of core pillar interconnect structures like 78, similar to FIG. 4. Each core pillar interconnect structure 78 provides one I/O terminal. The core pillar interconnect structures need a fine pitch to minimize its area and maximize the density of the interconnect array.

FIG. 6 describes the process of forming the core pillar interconnect structure 78. In step 80, the incoming wafer undergoes cleaning. In step 82, a metal contact pad 102 is formed on substrate 100 by sputtering or other suitable metal deposition process. Contact pad 102 is made of aluminum (Al), copper (Cu), or aluminum/copper alloys. Contact pad 102 is electrically connected to active and passive devices through conduction tracks or layers formed on substrate 100. An insulating layer 104 is formed over substrate 100 and contact pad 102. The insulating layer 104 can be made with SiN, SiO2, SiON, polyimide, BCB, PBO, or other insulating material. A portion of insulating layer 104 is removed by an etching process to expose contact pad 102.

An under bump metallization layer (UBM) 105 is deposited and patterned to electrically connect to contact pad 102. In one embodiment, UBM 105 may include a wetting layer, barrier layer, and adhesive layer. The adhesion layer is formed over insulating layer 104 for bonding to the barrier layer. The adhesion layer can be titanium (Ti), Al, titanium tungsten (TiW), and chromium (Cr). The barrier layer inhibits the diffusion of Cu into the active area of the die. The barrier layer can be made of nickel (Ni), Ni-alloy, platinum (Pt), palladium (Pd), TiW, and chromium copper (CrCu). The seed layer is formed over the barrier layer. The seed layer can be made with Cu, Ni, nickel vanadium (NiV), Cu, gold (Au), or Al. The seed layer follows the contour of insulating layer 104 and contact pad 102 and acts as an intermediate conductive layer formed between metal contact pad 102 and the core pillar.

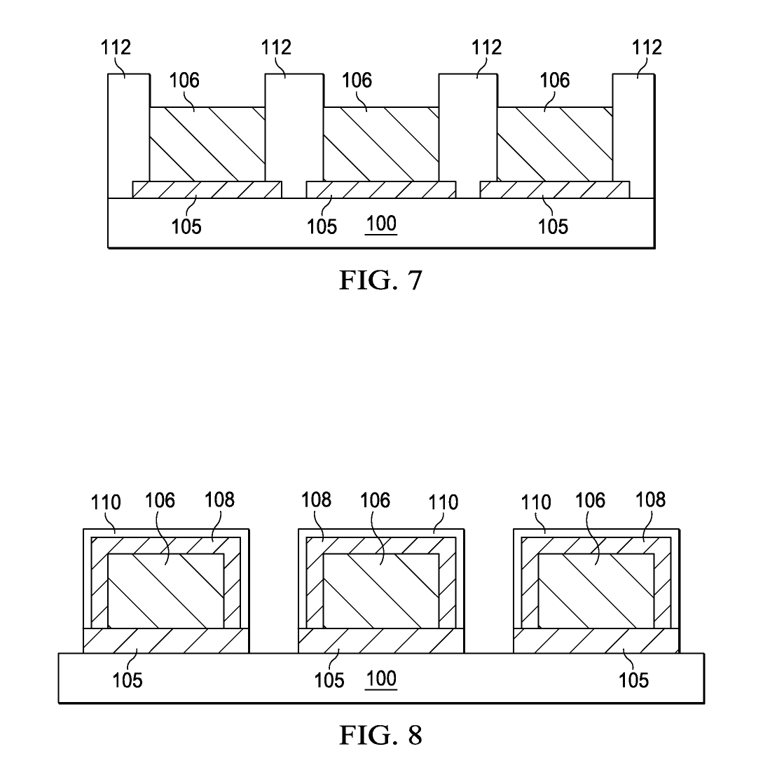

In steps 84 and 86 of FIG. 6, a photoresist layer 112 is coated, exposed, developed, and etched to form an opening or column having a width which is less than that of contact pad 102 and UBM 105. The opening in photoresist 112 is located central to contact pad 102 and UBM 105, as shown in FIG. 7. In step 88, an inner core pillar 106 is deposited into the opening between photoresist layers 112 by an electroless plating or electrolytic plating process. Core pillar 106 electrically connects to UBM 105 and contact pad 102. Core pillar 106 is made with Ni or other similar or suitable metal. Ni pillar plating is a simpler and lower cost process than the Cu pillar and solder plating of prior art step 38 in FIG. 2. In step 90, photoresist layer 112 is removed.

In step 92 of FIG. 6, a metal layer 108 is formed over core pillar 106. Metal layer 108 is deposited by an electroless plating or electrolytic plating process. Metal layer 108 is made with Cu or other similar or suitable metal. An organic solderability preservative (OSP) 110 is coated over metal layer 108 by dipping in an immersion tank.

In one embodiment, the OSP is formed by a series of processing steps including acidic cleaning of the underlying Cu layer 108, water rinse, micro-etch, water rinse, acid clean, water rinse, air knife, apply OSP, air knife, low pressure water rinse, and drying to expel moisture from the OSP coating and stabilize the materials. The micro-etch can use a hydrogen-peroxide sulfuric acid. The Cu metal layer 108 maintains a uniform and continuous OSP coating which completely fills the underlying surface. The immersion time is typically less than one minute at a temperature range of 40-45° C. The pH of the operating OSP solution should be maintained between 4.3 and 4.5. The OSP solution may contain benzotriazole, rosin, rosin esters, or benzimidazole compounds, as described in U.S. Pat. No. 5,173,130 and incorporated herein by reference. A typical benzimidazole compound may have an alkyl group of at least three carbon atoms at the 2-position dissolved in an organic acid. When the bare copper surface is immersed in OSP solution, the benzimidazole compound in an organic acid is converted to a copper complex. The copper complex reacts with the bare copper surface and forms a layer of benzimidazole and copper complex. By incorporating copper ions in the aqueous solution of the benzimidazole and acid, the reaction rate is enhanced.

Alternatively, the OSP coating can also be made with phenylimidazole or other imidazole compounds including 2-arylimidazole as the active ingredient, as described in U.S. Pat. No. 5,560,785 and incorporated herein by reference. In any case, the OSP coating 110 is made about 0.35 micrometers (μm) in thickness. The OSP coating 110 selectively protects the bare copper from oxidation, which if allowed to form could interfere with the solderability of the core pillar surface. FIG. 8 shows metal layer 108 plated over core pillar 106 and coated with OSP 110.

Note that core pillar 106 has been formed without deposition of solder material or reflow process. The absence of solder material deposition and reflow decreases the pitch of the core pillars and increases I/O density of the interconnect structure. The CU layer 108 and OSP coating 110 provides good solderability for core pillar 106 to the chip carrier substrate.

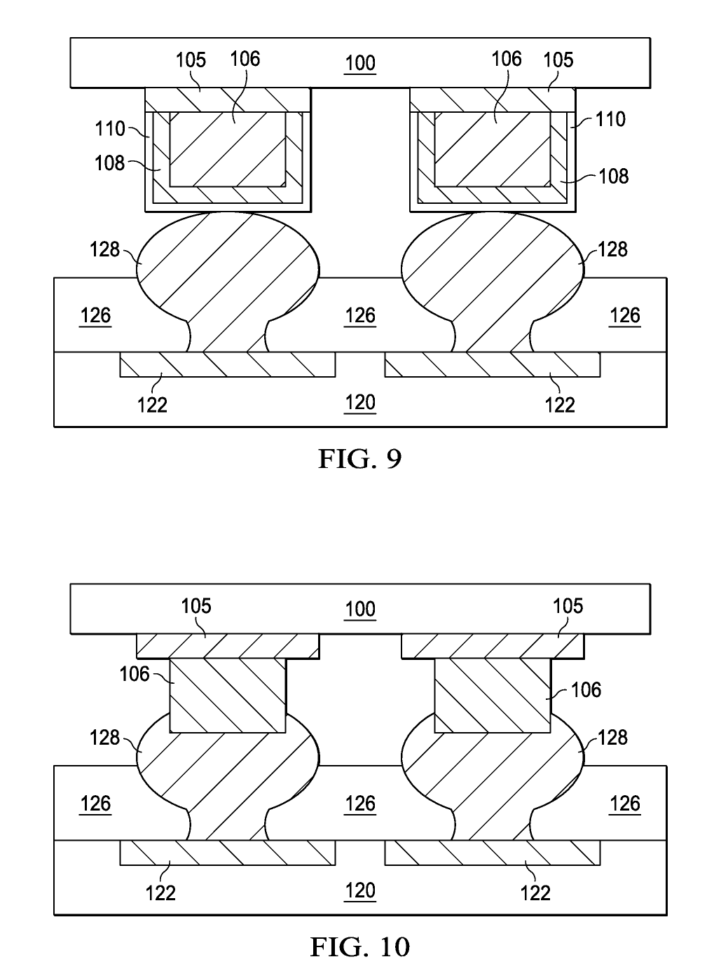

In FIG. 9, a chip carrier substrate 120 has contact pads or UBM 122 formed on its surface. The contact pad 122 can be Al, Cu, tin (Sn), Ni, Au, or silver (Ag). An insulating layer 126 is formed over substrate 120 and contact pads 122. A portion of insulating layer 126 is removed by an etching process to expose contact pads 122. An electrically conductive solder material is deposited in the insulating layer opening over contact pads 122 using an evaporation, electrolytic plating, electroless plating, ball drop, or screen printing process. The solder material can be any metal or electrically conductive material, e.g., Sn, lead (Pb), Ni, Au, Ag, Cu, bismuthinite (Bi), and alloys thereof. For example, the solder material can be eutectic Sn/Pb, high lead, lead free, or other solder materials. The solder material is reflowed by heating the solder material above its melting point to form solder bumps 128. In some applications, solder bumps 128 are reflowed a second time to improve electrical contact to contact pads 122.

The interconnect structure 78 of substrate 100, with Cu layer 108 and OSP coating 110 formed over core pillars 106, is brought into physical contact with solder bumps 128 on carrier substrate 120. The solder bumps 128 are reflowed to metallurgically and electrically connect core pillar 106 to the solder bumps, as shown in FIG. 10. The Cu layer 108 and OSP coating 110 provides good solderability characteristics while maintaining a fine core pillar pitch.

In summary, flip chips requiring a high-density interconnect array have many I/O terminals for routing electrical signals to external devices. The Ni core pillar with Cu outer layer and OSP coating, such as shown in FIG. 5, is used to decrease the pitch between the core pillars in the interconnect array. The pitch is smaller in part because the process requires no deposition of solder material or solder reflow process to form the core pillars. The decrease in core pillar pitch increases the number of I/O contacts per unit area on the semiconductor device. The density of the interconnect array can be increased by about 15%.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first substrate;
forming a contact pad over the first substrate;
forming an insulating layer over the first substrate and contact pad;
forming an under bump metallization (UBM) layer over the contact pad and insulating layer;
forming a plurality of core pillars over the UBM layer by electroless plating or electrolytic plating to reduce pitch and increase density of the core pillars;
depositing a copper layer over the core pillars; and
coating the copper layer over the core pillars with an organic solderability preservative (OSP) by,
(a) first acidic cleaning of the copper layer,
(b) first water rinsing the copper layer after the first acidic cleaning,
(c) micro-etching of the copper layer after the first water rinsing,
(d) second water rinsing of the copper layer after the micro-etching,
(e) second acid cleaning of the copper layer after the second water rinsing,
(f) third water rinsing of the copper layer after the second acid cleaning,
(g) first applying of air knife to the copper layer after third water rinsing,
(h) applying the OSP to the copper layer after the first applying of the air knife by immersion in an aqueous solution including copper ions and a benzimidazole, phenylimidazole or other imidazole compound for less than one minute at a temperature range of 40-45° C. to completely cover and protect the copper layer from oxidation,
(i) second applying of air knife to the OSP,
(j) fourth water rinsing of the OSP after the second applying of the air knife, and
(k) drying the OSP to expel moisture.

2. The method of claim 1, wherein forming the core pillars includes:
forming a photoresist layer over the first substrate;
removing a portion of the photoresist layer to form an opening over the UBM layer;
forming the core pillar in the opening of the photoresist; and
removing the photoresist layer.

3. The method of claim 1, wherein the OSP includes a thickness of about 0.35 micrometers.

4. The method of claim 1, further including disposing the opening in the photoresist layer central to the contact pad.

5. The method of claim 1, further including forming the copper layer by electroless plating or electrolytic plating.

6. The method of claim 1, further including:
providing a second substrate including a plurality of bumps formed over the second substrate; and
bonding the first substrate to the second substrate with the bumps electrically connected to the core pillars.

7. A method of making a semiconductor device, comprising:
providing a first substrate;
forming a plurality of core pillars over the first substrate by electroless plating or electrolytic plating;
depositing a conductive layer over the core pillars; and
forming an organic solderability preservative (OSP) over the conductive layer by,
(a) first acidic cleaning of the conductive layer,
(b) first water rinsing the conductive layer,
(c) micro-etching of the conductive layer,
(d) second water rinsing of the conductive layer,
(e) second acid cleaning of the conductive layer,
(f) third water rinsing of the conductive layer,
(g) applying the OSP to the conductive layer by immersion in an aqueous solution including copper ions,
(h) fourth water rinsing of the OSP, and
(i) drying the OSP to expel moisture.

8. The method of claim 7, further including:
forming a contact pad over the first substrate;
forming an under bump metallization (UBM) layer over the contact pad; and
forming the core pillars over the UBM layer.

9. The method of claim 7, wherein forming the core pillars includes:
forming a photoresist layer over the first substrate;
removing a portion of the photoresist layer to form an opening over the first substrate;
forming the core pillar in the opening of the photoresist; and
removing the photoresist layer.

10. The method of claim 7, wherein the conductive layer includes copper.

11. The method of claim 7, wherein the OSP is selected from a group consisting of benzotriazole, rosin, rosin esters, benzimidazole, phenylimidazole, and imidazole.

12. The method of claim 7, wherein the OSP includes a thickness of about 0.35 micrometers.

13. The method of claim 7, further including:
providing a second substrate including a plurality of bumps formed over the second substrate; and
bonding the first substrate to the second substrate with the bumps electrically connected to the core pillars.

14. A method of making a semiconductor device, comprising:
providing a first substrate;
forming a plurality of core pillars over the first substrate without reflow to reduce pitch and increase density of the core pillars;
depositing a conductive layer over the core pillars; and
forming an organic solderability preservative (OSP) over the conductive layer to completely cover and protect the conductive layer from oxidation.

15. The method of claim 14, wherein forming the OSP includes:
first acidic cleaning of the conductive layer;
first water rinsing the conductive layer;
micro-etching of the conductive layer;
second water rinsing of the conductive layer;
second acid cleaning of the conductive layer;
third water rinsing of the conductive layer;
applying the OSP to the conductive layer by immersion in an aqueous solution;
fourth water rinsing of the OSP; and
drying the OSP to expel moisture.

16. The method of claim 14, wherein the OSP is selected from a group consisting of benzotriazole, rosin, rosin esters, benzimidazole, phenylimidazole, and imidazole.

17. The method of claim 14, further including:
forming a contact pad over the first substrate;
forming an under bump metallization (UBM) layer over the contact pad; and
forming the core pillars over the UBM layer.

18. The method of claim 14, wherein forming the core pillars includes:
forming a photoresist layer over the first substrate;
removing a portion of the photoresist layer to form an opening over the first substrate;
forming the core pillar in the opening of the photoresist; and
removing the photoresist layer.

19. The method of claim 14, further including forming the core pillars over the first substrate by the electroless plating or electrolytic plating.

20. The method of claim 14, further including:
providing a second substrate including a plurality of bumps formed over the second substrate; and
bonding the first substrate to the second substrate with the bumps electrically connected to the core pillars.

21. A semiconductor device, comprising:
a first substrate;
a plurality of core pillars electroless plated or electrolytic plated over the first substrate;
a conductive layer formed over the core pillars; and
an organic solderability preservative (OSP) completely covering the conductive layer to protect the conductive layer from oxidation.

22. The semiconductor device of claim 21, further including:
a contact pad formed over the first substrate; and
an under bump metallization (UBM) layer formed over the contact pad.

23. The semiconductor device of claim 21, wherein the OSP is selected from a group consisting of benzotriazole, rosin, rosin esters, benzimidazole, phenylimidazole, and imidazole.

24. The semiconductor device of claim 21, wherein the OSP includes a thickness of about 0.35 micrometers.

25. The semiconductor device of claim 21, further including a second substrate including a plurality of bumps formed over the second substrate, wherein the first substrate is bonded to the second substrate with the bumps electrically connected to the core pillars.
